(19) United States
(12) Patent Application Publication
(10) Pub. No.: US 2014/0332069 A1
(43) Pub. Date: Nov. 13, 2014

(54) CONTROLLED EXPANSION FLEXIBLE METAL SUBSTRATE MATERIAL HAVING A TEXTURED STRUCTURE

(71) Applicant: KOREA INSTITUTE OF INDUSTRIAL TECHNOLOGY, Chungcheongnam-do (KR)

(72) Inventors: Tai Hong Yim, Gyeonggi-do (KR); Heung Yeol Lee, Gyeonggi-do (KR); Min Su Lee, Gyeonggi-do (KR); Yoon Ho Han, Incheon (KR)

(21) Appl. No.: 14/358,138

(22) PCT Filed: Oct. 16, 2012
(86) PCT No.: PCT/KR2012/008429

§ 371 Date: May 14, 2014

(30) Foreign Application Priority Data
Nov. 17, 2011 (KR) 10-2011-0120181
Oct. 15, 2012 (KR) 10-2012-0114243

(51) Int. Cl. H01L 31/0236; C25D 1/00; G02B 5/18

(52) U.S. Cl. CPC H01L 31/02366; G02B 5/1866; C25D 1/003
USPC 136/256; 428/603; 205/76

(57) ABSTRACT

The present invention relates to a controlled expansion flexible metal substrate material and to a production method therefor. In the present invention, an electrocasting method is used in order to produce a metal substrate material which comprises a controlled expansion alloy and has a textured structure and a wide width. Also, the flexible metal substrate material of the present invention can be used as the substrate for a silicon thin-film solar cell since the Fe—Ni alloying compositional ratio is controlled in such a way that the thermal expansion coefficient approximates that of silicon. The present invention is devised in such a way that the optical pathway is extended and the photoelectric conversion efficiency is improved since a textured structure is provided on the surface of a flexible metal substrate material by forming a textured structure on the surface of a plating drum used as a plating cathode or anode used in an electrocasting method.

### TECHNICAL FIELD

The present invention relates to a flexible metal substrate material having a textured structure similar to that of a crystalline silicon solar cell, and more particularly to a flexible metal substrate material for a solar cell, which has a textured structure having a thermal expansion behavior similar to that of the material of a thin-film cell that is deposited thereon.

### BACKGROUND ART

A substrate material for a flexible solar cell is required to have excellent mechanical strength and preferably has a thermal expansion behavior similar to that of the material of a thin-film cell, which is deposited thereon, at the temperature of a solar cell fabrication process. When a substrate satisfies such requirements, the reduction in efficiency resulting from separation between the substrate and a material deposited thereon can be inhibited.

Substrates for flexible solar cells, which are currently frequently used, include plastic substrates such as PI polyimide (PI) and polyethylene terephthalate (PET) substrates, and metal foil substrates such as Ti, Mo, SS and kover substrates. However, plastic substrates have disadvantages, including low heat resistance, a high coefficient of thermal expansion (CTE), low strength, and low resistances to chemicals, oxygen and moisture.

Meanwhile, metal substrates can overcome the disadvantages of the plastic substrates. The metal substrate is required to have a thin thickness so as to be flexible. To satisfy this requirement, rolling process technology is used. In the rolling process technology, a metal sheet is processed to have a thin thickness by a system having a 20-stage rolling mill. However, the rolling process technology has limitations in increasing the width of the metal substrate material and is difficult to reduce the thickness of the substrate material to 0.1 mm or smaller. In addition, it has disadvantages in that the thermal expansion coefficient of the substrate material cannot be controlled and the substrate material is difficult to handle.

Generally, in the case of silicon solar cells, an increase in the path of incident sunlight in the light-absorbing layer leads to an increase in the photoelectric conversion efficiency, and for this reason, the so-called texturing process for forming a pyramidal textured structure on the surface is performed. In addition, in the case of silicon thin-film solar cells, a thin layer having a textured structure is deposited on the substrate. However, these texturing processes cause additional efforts and costs, resulting in an increase in the production cost.

For the fabrication of display devices on flexible substrates or grating devices requiring a fine textured structure, in addition to silicon thin-film solar cells, a flexible thin metal substrate material may be used. Production technology is required which can produce a flexible thin metal substrate material having a large width, is more cost-effective and can provide handling convenience.

### DISCLOSURE

### Technical Problem

It is an object of the present invention to provide a flexible metal substrate material for a solar cell which is produced at low costs and has a textured structure. Another object of the present invention is to produce a flexible metal substrate material having a large width, which can be used for silicon thin-film solar cells, display devices, grating devices and the like and is produced using a simpler system.

Still another object of the present invention is to provide a flexible metal substrate material which has thermal expansion properties most suitable for a silicon solar cell, is flexible and results in an increase in photoelectric conversion efficiency, as a result of controlling the alloy composition, grain size and structure of the metal substrate material.

### Technical Solution

In order to accomplish the above objects, in accordance with a preferred embodiment of the present invention, there is provided a flexible metal substrate material for a solar cell, the substrate material having a textured structure on its surface, wherein the textured structure is formed by an electroforming process using a plating drum or plate having a textured structure on its surface.

The flexible metal substrate material may be a substrate material composed of an Fe-40 to 45 wt % Ni alloy foil.

According to another preferred embodiment of the present invention, the flexible metal substrate material may have micro-sized grains formed by heat treatment at a temperature of 350˜1000° C. for 30 minutes to 2 hours after producing the substrate material by the electroforming process.

The flexible metal substrate material may have a grain size between 0.1 μm to 10 μm and a single-phase face-centered cubic structure.

The flexible metal substrate material may have a coefficient of thermal expansion between 2×10⁻⁶/° C. and 6×10⁻⁶/° C.

According to still another embodiment of the present invention, the flexible metal substrate material may have a thickness between 1 μm and 100 μm.

In accordance with a still another preferred embodiment of the present invention, there is provided a method for producing a flexible metal substrate material for a solar cell, the method including the steps of: forming a metal substrate having a textured structure on its surface by an electroforming process using a plating drum or plate having a textured structure on its surface; and heat-treating the metal substrate, formed by the electroforming process, to form micro-sized grains.

According to a still another preferred embodiment of the present invention, there is provided a flexible metal substrate material for grating, which is composed of a Fe-40 to 45 wt % Ni alloy and has a coefficient of thermal expansion between 2×10⁻⁶/° C. and 6×10⁻⁶/° C.

According to a still another preferred embodiment of the present invention, the flexible metal substrate material for grating may have a concave-convex structure for grating formed on the surface or a textured structure on the surface.

### Advantageous Effects

According to the present invention, a thin flexible metal substrate material having a desired width can be produced by an electroforming process. Also, according to the present invention, a thin metal substrate material composed of an Fe—Ni alloy has a desired coefficient of thermal expansion by controlling the composition of an electrolyte. Further, according to the present invention, a thin flexible metal substrate material having a textured structure on the surface is produced using a simple system. In addition, according to the present invention, silicon thin-film solar cells, compound semiconductor solar cells such as CIGS solar cells, grating devices, display devices and the like can be fabricated at relatively low costs using the flexible metal substrate material having the textured structure.

### DESCRIPTION OF DRAWINGS

FIG. 1 is a cross-sectional view of a flexible metal substrate material produced by an electroforming process according to a preferred embodiment of the present invention.

FIG. 2 is a conceptual view showing an extended light path in a pyramidal textured structure (a flexible metal substrate material having an inclination angle of 60°) similar to the textured structure of a silicon thin-film solar cell, which is produced according to a preferred embodiment of the present invention.

FIG. 3 is a schematic view of a textured flexible metal substrate material for a grating device, which is produced according to a preferred embodiment of the present invention.

FIG. 4 shows the coefficient of thermal expansion of a metal foil substrate material composed of Fe-40 wt % Ni as a function of the temperature of a structure stabilization process.

FIG. 5 shows the coefficient of thermal expansion of a metal foil substrate material composed of Fe-42 wt % Ni as a function of the temperature of a structure stabilization process.

FIG. 6 shows the XRD peak of a metal foil substrate material composed of Fe-42 wt % Ni as a function of heat-treatment temperature.

FIG. 7 shows the coefficient of thermal expansion of a metal foil substrate material composed of Fe-44 wt % Ni as a function of the temperature of a structure stabilization process.

FIG. 8a shows the results of measuring the surface reflectance of a substrate material having a flat structure.

FIG. 8b shows the results of measuring the surface reflectances of substrate materials, which have a textured surface structure and comprise V-shaped textured structures whose inclination angles are 30° (a), 45° (b) and 60° (c), respectively, and substrate materials which have a textured surface structure and comprise pyramid-shaped textured structures whose inclination angles are 30° (d), 45° (e) and 60° (f), respectively.

FIG. 9 shows the results of measuring the hardness of a metal foil substrate material composed of Fe-42 wt % Ni at varying annealing temperatures.

### BEST MODE

Hereinafter, preferred embodiments of the present invention will be described in detail with reference to the accompanying drawings.

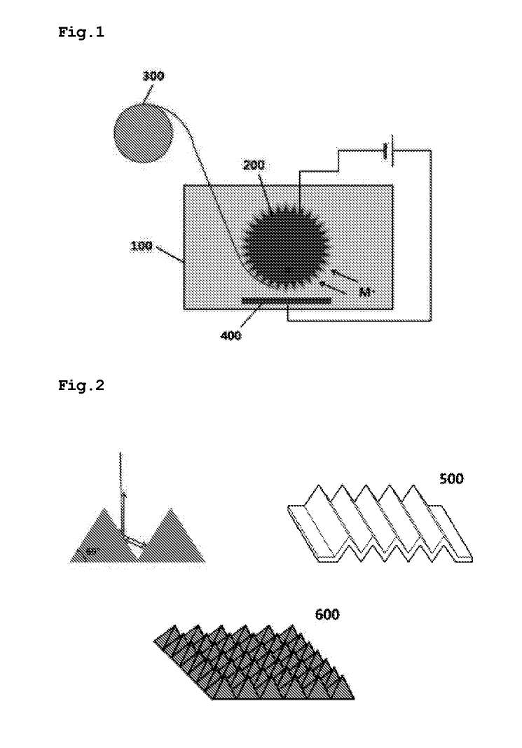

FIG. 1 shows an example of producing a flexible metal substrate material by electroforming according to the present invention.

Referring to FIG. 1, an electrolyte solution is filled in an electrolytic cell 100 made of an electrically conductive metal such as SUS (steel use stainless) steel, and a plating drum 200 having an electrically conductive metal surface and a positive electrode 400 are immersed in the electrolyte solution. Then, when a voltage is applied to the positive electrode 400 and the plating drum 200, metals are deposited on the surface of the plating drum 200 according to the electroplating principle to form a metal foil. The formed metal foil is flexible and the thickness thereof is controllable. The thickness of the metal foil is controlled, thereby producing a flexible metal substrate material.

The plating drum 200 is connected to the negative (−) pole of a voltage source, and the positive electrode 400 is connected to the positive (+) pole of the voltage source. An electrolyte solution containing metal ions to be plated is filled in the electrolytic cell 100. In this case, the metal foil formed by electroforming can be made of a desired alloy material determined depending on the composition of the electrolyte solution.

In the present invention, a textured structure is formed on the surface of the plating drum 200 so that a metal foil that is produced by electroplating has the same textured structure on its surface. As used herein, the term “textured structure” is meant to include textured structures having various cross-sectional shapes such as a V shape and a U shape. A method for forming a textured structure on the surface of the plating drum 200 may be selected from among various methods well known in the art, including physical and chemical surface treatment techniques.

In addition, the width of the metal foil that is produced by electroforming can be increased to a desired width by increasing the size of the drum, suggesting that the electroforming process is advantageous over a rolling process.

Although FIG. 1 illustrates the continuous production method based on the roll-to-roll process, the roll-to-roll process does not necessarily need to be used. In other words, a plate having a textured structure is connected to a negative (−) pole and immersed in an electrolytic cell, and in this state, a flexible metal substrate having a textured structure can be produced by a batch process. Even when the batch process is used, a metal foil having a desired large width and thin thickness can be produced.

The present inventors have conducted extensive studies on the thermal expansion behavior of an iron-nickel alloy foil by electroforming for a considerable period of time, and as a result, have identified the thermal expansion behavior of an iron-nickel alloy according to the composition of the alloy. The results of the studies indicated that the thermal expansion coefficient of an Fe-40 to 45 wt % Ni alloy material is almost consistent with the thermal expansion coefficient of a silicon (Si) thin-film solar cell device.

In the case of a silicon thin-film solar cell, if the silicon thin film is formed on a plastic or glass substrate using an evaporation source, problems such as interlayer distortion and separation will occur. To overcome such problems, a low-temperature deposition technique that reduces the heating temperature of an evaporation source should be developed, but the thermal deformation of the resulting device during use after fabrication is problematic. A substrate made of an Fe-40 to 45 wt % Ni alloy material according to the present invention has thermal expansion properties almost similar to those of a silicon thin film, and thus makes it possible to fabricate a device with high efficiency at high temperature using an existing system without having to use a special low-temperature deposition system in the fabrication process. In addition, it has an advantage in that the thermal deformation of the device does not occur even upon generation of heat during use, suggesting that the life span of the device can be extended.

The Fe-40 to 45 wt % Ni alloy material that is produced in the present invention may have a coefficient of thermal expansion between 2×10⁻⁶/° C. and 6×10⁻⁶/° C. More specifically, it may have a coefficient of thermal expansion of 4×10⁻⁶/° C. as a result of controlling the composition of the alloy.

To produce the substrate material having the above-described alloy composition, the electrolyte solution may contain, as an electrolyte, a mixture of an iron-containing salt and a nickel-containing salt. In a preferred embodiment of the present invention, the electrolyte may comprise iron sulfate, ferrous chloride, nickel sulfate, nickel chloride, and nickel sulfamate. More preferably, the electrolyte comprises ferrous chloride and nickel sulfamate.

To obtain an alloy composition composed of Fe-40 to 45 wt % Ni, the electrolyte solution preferably contains 100-300 g/L of nickel sulfamate and 10-40 g/L of iron chloride. The electrolyte solution is controlled to a pH of 2.5-3.5, a temperature of 45˜60° C. and a current density of 50-120 mA/cm². However, the conditions related to the electrolyte solution can be suitably controlled according to circumstances.

In addition to the electrolyte, additives such as a brightener, a stress-relieving agent and a pH-buffering agent are preferably added. Preferably, the electrolyte solution contains 1-10 g/L of saccharin, 0.1-5 g/L of ascorbic acid, 10-40 g/L of boronic acid, and 0.1-5 g/L of sodium dodecyl sulfate.

The plating drum 200 may be rotated at a predetermined speed, and the foil formed by electroplating can be recovered in a simple manner by winding it around a roller 300 disposed outside the electrolytic cell 100. The thickness of the metal foil is associated with the rotating speed of the plating drum 200, and the thickness of the metal foil can be controlled to a desired thickness by controlling the rotating speed of the negative electrode drum depending on the size of the drum and the current density. In the present invention, the thickness of the Fe—Ni metal foil substrate material is preferably 1-100 μm, and preferably 10-50 μm. If the thickness of the substrate material is 100 μm or more, the application of the substrate material will not be problematic, but productivity will be reduced. Because such a thin metal foil substrate is flexible, it can be used for solar cells, display devices and the like, which require flexibility.

As can be seen in FIG. 2, in the case of a metal foil substrate material having a textured structure consisting of continuous V-shaped cross-sectional portions, the light path in which perpendicularly incident light is reflected according to the law of reflection is much longer than that in a flat surface. In a textured substrate 500 according to the present invention, three-dimensional textured structures such as a triangular pyramid and a square pyramid 600, in addition to the V-shaped cross-sectional portion, may be formed on the surface. When the metal foil substrate material is used as a substrate for a silicon thin-film solar cell, it can extend the path of light incident on the fabricated solar cell to increase the photoelectric conversion efficiency.

Particularly, when the textured structure consisting of continuous V-shaped cross-sectional portions has an inclination angle of 60° or more, the path of light can be significantly extended, because perpendicularly incident light is reflected three times and returned back along the incident path.

In addition, a grating substrate 700 produced using a plating drum comprising a textured structure having a specific shape is also within the scope of the present invention.

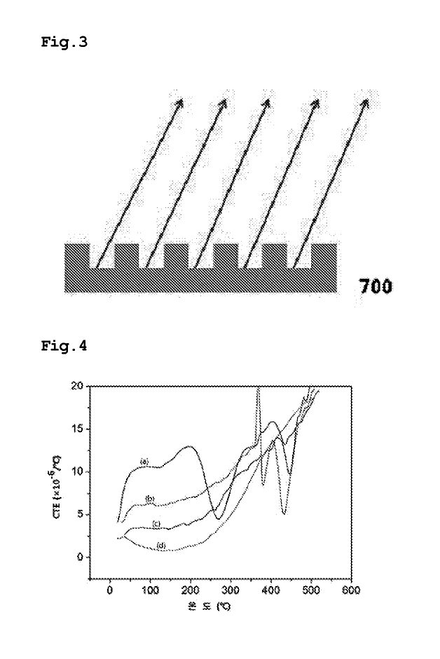

FIG. 3 shows another example of a metal foil substrate material produced in the present invention, in which the metal substrate material has a textured structure, is produced by an electroforming process and is used for a grating device that is used to make hologram labels by the diffraction and interference of light. In this case, the alloy material does not need to be composed of iron and nickel and may be composed of a material having desired physical properties.

The flexible metal substrate material having a textured structure, which is produced by an electroforming process in a cost-effective and simple manner so as to have a desired size, can be used as a substrate for solar cells, display devices and grating devices.

The metal foil substrate material produced by the electroforming process as described above is a nanocrystalline material having a grain size of about 10-30 nm. This nanocrystalline substrate material has high mechanical properties compared to a bulk material having the same composition, which is produced by a conventional rolling process. However, it has a problem in that it shows a rapid change in the thermal expansion behavior due to a change in the structure thereof at a specific temperature. In materials having a nanocrystalline structure, the structural relaxation of atoms in a non-equilibrated state occurs as the temperature increases. When the critical temperature is reached, some nanocrystalline grains whose structural relaxation proceeded fastest start to grow and spread throughout the material, causing thermal shrinkage. This can cause problems in a process of fabricating a device at high temperature, and for this reason, a process of stabilizing the structure is required.

To overcome this problem, in the present invention, the metal foil produced by the electroforming process was subjected to a structure stabilization process by heat-treating the produced metal foil at a temperature of 350˜1000° C. for 30 minutes to 2 hours. During the heat-treatment process, the grains of the metal foil grow, and the size and texture of the grains change.

In the present invention, through the structure stabilization process (i.e., heat treatment), the size of the nano-sized grains of the metal foil was increased to a grain size of 0.1-10 μm so that the metal foil showed a uniform thermal expansion behavior.

As the heat-treatment temperature increases, the structure of the substrate material also changes. That is, it has a single-phase face-centered cubic (FCC) structure. Generally, nanocrystalline materials have different structures, including a body-centered cubic structure and a face-centered cubic structure. However, the substrate material of the present invention has a single-phase face-centered cubic structure, and thus shows specific thermal expansion properties. Preferably, it has a coefficient of thermal expansion between 2×10⁻⁶/° C. and 6×10⁻⁶/° C. This coefficient of thermal expansion is almost similar to that of silicon, and the substrate material of the present invention may most preferably be used for silicon solar cells.

As the size of grains in the stabilized structure of the substrate material increases, the tensile strength decreases, but the flexibility increases, the substrate material can be advantageously used as a substrate material for a silicon solar cell. However, even the substrate material having increased grain size shows a tensile strength higher than that of a substrate material produced by a conventional rolling process.

The grain size of the substrate material is preferably between 0.1 μm and 10 μm. If the grain size of the substrate material is less than 0.1 μm, the thermal expansion coefficient will change rapidly with a change in temperature, suggesting that the substrate material will not have a stable thermal expansion coefficient. If the grain size is more than 10 μm, the strength will decrease, making it difficult to handle the substrate material.

### MODE FOR INVENTION

Hereinafter, the present invention will be described in detail with reference to examples, but the scope of the present invention is not restricted or limited to these examples.

### EXAMPLE 1

A metal substrate composed of Fe-40 wt % Ni was produced using an electrolyte solution and an electroforming system comprising a plating drum having a pyramidal textured structure as shown in FIG. 1. Specifically, the electrolyte solution contained 30 g/L of iron (II) chloride 4-hydrate, 200 g/L of nickel sulfamate, 20 g/L of boronic acid, 1 g/L of sodium dodecyl sulfate, 2 g/L of saccharin and 1 g/L of an antioxidant. The electrolyte solution was maintained at a temperature of 60° C. and controlled to a current density of 56 mA/cm², thereby producing a metal foil substrate material composed of Fe-40 wt % Ni and having a thickness of 30 μm.

The textured structure in the produced substrate material had an inclination angle of 60°, and the grain size was 15-20 nm. When the produced substrate material was subjected to a structure stabilization process by heat treatment at a temperature of 400˜1000° C. for 1 hour, the grain size increased to 0.1-10 μm.

In the cases of (a) the produced substrate material was not subjected to a structure stabilization process, (b) it was subjected to a structure stabilization process by heat-treatment at 400° C. for 1 hour, (c) it was subjected to a structure stabilization process by heat-treatment at 500° C. for 1 hour, and (d) it was subjected to a structure stabilization process by heat-treatment at 600° C. for 1 hour, the thermal expansion coefficient of the Fe—Ni metal foil substrate material as a function of the temperature of the structure stabilization process was measured by thermo-mechanical analysis (TMA), and the results of the measurement are shown in FIG. 4. The thermal expansion coefficient was measured in the temperature range of 25˜520° C. at a heating rate of 5° C./min. As can be seen in FIG. 4, when the structure stabilization process was performed at 400° C., rapid thermal shrinkage at about 400° C. occurred. However, when the structure stabilization process was performed at 600° C., the average of CTEs in the temperature range up to 300° C. was 2.01×10⁻⁶/° C.

### EXAMPLE 2

A metal foil substrate material composed of Fe-42 wt % Ni was produced in a manner similar to that described in Example 1 using an electrolyte solution having a composition controlled to provide Fe-42 wt % Ni. The textured structure in the produced substrate material had a pyramidal shape having an inclination angle of 60°. When the produced substrate material was subjected to a structure stabilization process at a temperature of 400˜1000° C., the grain size increased to 0.1-10 μm.

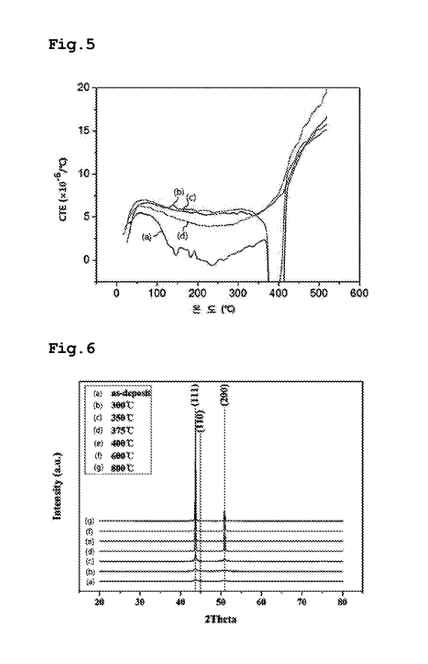

In the cases of (a) the produced substrate material was not subjected to a structure stabilization process, (b) it was subjected to a structure stabilization process at 400° C., (c) it was subjected to a structure stabilization process at 500° C., and (d) it was subjected to a structure stabilization process at 600° C., the thermal expansion coefficient of the Fe—Ni metal foil substrate material as a function of the temperature of the structure stabilization process was measured by thermo-mechanical analysis (TMA), and the results of the measurement are shown in FIG. 5. The thermal expansion coefficient was measured in the temperature range of 25˜520° C. at a heating rate of 5° C./min. As can be seen in FIG. 5, when the substrate material was not subjected to the structure stabilization process, it showed a rapid thermal change at about 375° C. Also, when the structure stabilization process was performed at 400° C., rapid thermal shrinkage at about 400° C. occurred. However, when the structure stabilization process was performed at 600° C., the average of CTEs in the temperature range up to 350° C. was 4.94×10⁻⁶/° C.

In addition, the XRD peaks of the produced substrate material at varying heat-treatment temperatures were measured to confirm the structures. The results of the measurement are shown in FIG. 6. As shown in FIG. 6, as the heat-treatment temperature increased, the peaks of FCC (111) and FCC (200), which indicate a face-centered cubic structure, clearly appeared. Meanwhile, the peak of FCC (110) disappeared when the heat treatment was performed at 600° C. or higher.

In addition, the grain sizes of the produced substrate materials at varying heat-treatment temperatures were measured. The results of the measurement are shown in Table 1 below.

TABLE 1

| | |
|---|---|
| Heat treatment | Grain size (μm) |

| temperature (° C.) | Optical | SEM |
|---|---|---|
| 400 | 1.73 | 1.77 |
| 600 | 2.56 | 2.13 |
| 800 | 4.27 | 4.50 |

As can be seen in Table 1 above, the grain size constantly increased as the heat treatment temperature increased. Also, the specimen heat-treated at 800° C. showed a grain size of 4.3 μm, as observed by an optical microscope, and a grain size of 4.5 μm as observed by an SEM microscope.

### EXAMPLE 3

A metal foil substrate material composed of Fe-44 wt % Ni was produced in a manner similar to that described in Example 1 using an electrolyte solution having a composition controlled to provide Fe-44 wt % Ni. The textured structure in the produced substrate material had a pyramidal shape having an inclination angle of 60°. When the produced substrate material was subjected to a structure stabilization process at a temperature of 400˜1000 t, the grain size increased to 0.1-10 μm.

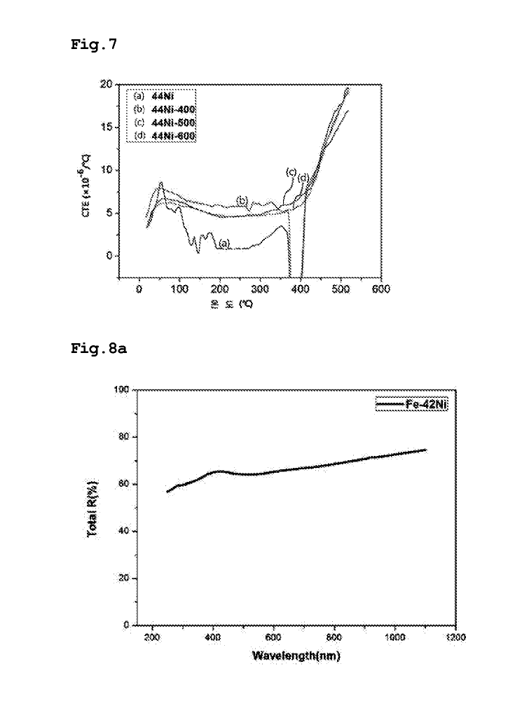

In the cases of (a) the produced substrate material was not subjected to a structure stabilization process, (b) it was subjected to a structure stabilization process at 400° C., (c) it was subjected to a structure stabilization process at 500° C., and (d) it was subjected to a structure stabilization process at 600° C., the thermal expansion coefficient of the Fe—Ni metal foil substrate material as a function of the temperature of the structure stabilization process was measured by thermo-mechanical analysis (TMA), and the results of the measurement are shown in FIG. 7. The thermal expansion coefficient was measured in the temperature range of 25˜520° C. at a heating rate of 5° C./min. As can be seen in FIG. 7, when the structure stabilization process was performed at 400° C., rapid thermal shrinkage at about 400° C. occurred. However, when the structure stabilization process was performed at 600° C., the average of CTEs in the temperature range up to 400° C. was 5.33×10⁻⁶/° C.

### TEST EXAMPLE 1

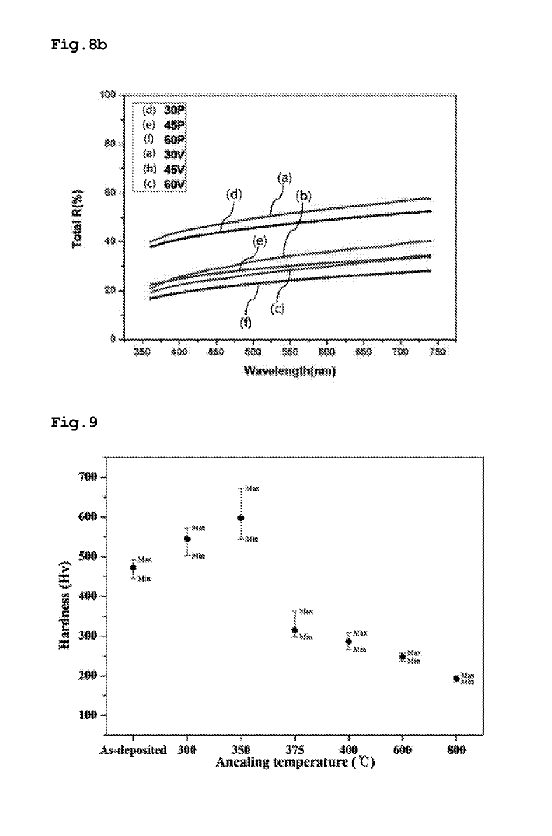

Metal foil substrate materials composed of Fe-42 wt % Ni were produced using the electrolyte solution having the composition described in Example 2 and the electroforming system. The textured structures in the produced substrate materials had V-shapes having inclination angles of 30°, 45° and 60°, respectively, and pyramidal shapes having inclination angles of 30°, 45° and 60°, respectively. The surface reflectance of each of the produced substrate materials was measured, and the results of the measurement are shown in FIGS. 8a and 8b.

FIG. 8a shows the results of measuring the total reflectance of a substrate material having no textured structure formed thereon, and FIG. 8b shows the results of measuring the total reflectance of the substrates having V-shaped textured structures whose inclination angles were 30° (a), 45° (b) and 60° (c), respectively, and the substrate materials having pyramidal textured structures whose inclination angles were 30° (d), 45° (e) and 60° (f), respectively.

The flat substrate material having no textured structure formed on the surface (FIG. 7a) showed a high reflectance compared to the substrate materials having textured structures on the surfaces (FIG. 8b). In addition, as can be seen in FIG. 8b showing a comparison of the measured reflectance between the pyramidal shapes and the V-shapes, the total reflectance of the two shapes constantly decreased as the inclination angle increased. Among these shapes, the pyramidal shape (f) having an inclination angle of 60° showed the lowest total reflectance. This suggests that, when the substrate comprising the pyramid-shaped textured structure having an inclination angle of 60° is used as a substrate for a silicon thin-film solar cell, the path of light in the solar cell becomes the longest, resulting in an increase in the photoelectric conversion efficiency.

### TEST EXAMPLE 2

For the metal foil substrate material produced in Example 2, the hardness of the substrate material at varying temperatures of the structure stabilization process was measured. The results of the measurement are shown in FIG. 9. FIG. 9 shows the highest, lowest and average values of the hardness at varying heat-treatment (annealing) temperatures. As can be seen in FIG. 9, the average value of the hardness of the substrate before and after the electroforming process was 472.02 Hz, but the hardness value greatly increased to 592.5 Hz after heat-treatment (annealing) at 350° C. As the annealing temperature increased from 350° C., the hardness value decreased continuously and decreased to 193.6 Hz at 800° C. This is believed to be attributable to the growth of grains due to the increase in the annealing temperature. The generation and movement of dislocation in micro-sized grains are possible, and thus it is expected that the heat-treated (annealed) substrate material will be flexible compared to an electrodeposited nanocrystalline material having little or no flexibility.

### DESCRIPTION OF THE REFERENCE NUMERALS IN THE DRAWINGS

100: electrolytic cell;

200: plating drum;

300: roller;

400: positive electrode;

500: substrate comprising a textured structure having a V-shaped textured shape;

600: substrate having a pyramid-shaped textured structure;

700: grating substrate.

1. A flexible metal substrate material for a solar cell, the substrate material having a textured structure on its surface, wherein the textured structure is formed by an electroforming process using a plating drum or plate having a textured structure on its surface.

2. The flexible metal substrate material of claim 1, wherein the flexible metal substrate material is a substrate material composed of an Fe-40 to 45 wt % Ni alloy foil.

3. The flexible metal substrate material of claim 1, wherein the flexible metal substrate material has micro-sized grains formed by heat treatment at a temperature of 350˜1000° C. for 30 minutes to 2 hours.

4. The flexible metal substrate material of claim 1, wherein the flexible metal substrate material has a grain size between 0.1 is to 10 is and a single-phase face-centered cubic structure.

5. The flexible metal substrate material of claim 1, wherein the flexible metal substrate material has a coefficient of thermal expansion between 2×10⁻⁶/° C. and 6×10⁻⁶/° C.

6. The flexible metal substrate material of claim 1, wherein the flexible metal substrate material has a thickness between 1 μm and 100 μm.

7. A method for producing a flexible metal substrate material for a solar cell, the method comprising the steps of:
forming a metal substrate having a textured structure on its surface by an electroforming process using a plating drum or plate having a textured structure on its surface; and
heat-treating the metal substrate, formed by the electroforming process, to form micro-sized grains.

8. The method of claim 7, wherein the metal substrate is composed of an Fe-40 to 45 wt % Ni alloy.

9. A flexible metal substrate material for grating, which is composed of an Fe-40 to 45 wt % Ni alloy and has a coefficient of thermal expansion between 2×10⁻⁶/° C. and 6×10⁻⁶/° C.

10. The flexible metal substrate material of claim 9, which has a convex-concave structure for grating formed on the surface.

11. The flexible metal substrate material of claim 9, which has a textured structure on the surface.

12. The flexible metal substrate material of claim 9, which has a grain size between 0.1 μm and 10 μm.
